(19) United States
(12) Patent Application Publication
(10) Pub. No.: US 2021/0358990 A1
(43) Pub. Date: Nov. 18, 2021

(54) SMALL-SIZE INFRARED SENSOR STRUCTURE AND MANUFACTURING METHOD THEREFOR

(71) Applicant: SHANGHAI IC R&D CENTER CO., LTD., Shanghai (CN)

(72) Inventors: Xiaoxu KANG, Shanghai (CN); Yuhang ZHAO, Shanghai (CN)

(21) Appl. No.: 16/624,914

(22) PCT Filed: Dec. 22, 2017
(86) PCT No.: PCT/CN2017/118010

§ 371 Date: Dec. 20, 2019

(30) Foreign Application Priority Data
Jun. 27, 2017 (CN) 201710500092.3

(51) Int. Cl. H01L 27/146

(52) U.S. Cl. CPC H01L 27/14636; H01L 27/14683; H01L 27/14607; H01L 27/14649

(57) ABSTRACT

The present disclosure discloses a small-size infrared sensor structure and a manufacturing method therefor. Trench is etched in a conductive beam region, and the conductive beam is formed by the sidewall of the trench, so that the small-size infrared sensor structure with adjacent pixel structures can share one conductive support hole, thereby improving integration degree of the pixels, enlarging the regions of the infrared detection regions of the pixels, and improving infrared detection efficiency.

### CROSS-REFERENCE TO RELATED APPLICATION

This application claims priority of International Patent Application Serial No. PCT/CN2017/118010, filed Dec. 22, 2017, which is related to and claims priority of Chinese patent application serial No. 201710500092.3, filed Jun. 27, 2017. The entirety of each of the above-mentioned patent applications is hereby incorporated herein by reference and made a part of this specification.

### TECHNICAL FIELD

The present disclosure relates to the technical field of semiconductor integrated circuit manufacturing processes, in particular to a small-size infrared sensor structure and a manufacturing method thereof.

### BACKGROUND

An infrared sensor is usually using sensitive materials to sense the infrared light emitted by a substance that needs to be detected, and the detected infrared light signals are transmitted to an external circuit by an electrical connection layer. In the working process of a traditional infrared sensor, loss rate of the infrared light entering the infrared sensor is high, and the detection sensitivity is reduced. In general, the loss rate of the infrared light is usually reduced by reducing the size of infrared sensors.

However, due to the limitation of existing lithographing and etching process conditions, the manufacturing process of the small-size infrared sensor structure is complex and with high process cost.

### SUMMARY

The present disclosure aims to overcome the defects in the prior art, in order to overcome the above problems, the present disclosure aims to provide a small-size infrared sensor structure and a manufacturing method thereof, thereby simplifying the manufacturing process.

In order to achieve the object, the present disclosure provides a small-size infrared sensor structure, comprising: a plurality of pixels, each pixel has an infrared detection region, a conductive beam electrically connected to the infrared detection region, and a conductive support hole used for supporting the conductive beam and electrically connected with the conductive beam, wherein adjacent pixel structures are commonly connected to one conductive support hole through the conductive beam.

Preferably, wherein the commonly connected conductive support hole is arranged below the adjacent infrared detection regions; taking the centerline of the commonly connected conductive support hole as a symmetry axis, the adjacent pixel structures are in the mirror symmetry.

Preferably, wherein the sidewall of the conductive beam and the sidewall of the conductive support hole are arranged in the same layer successively, wherein the hierarchical structure of the conductive beam and that of the sidewall of the conductive support hole are same, each layer of the conductive beam and corresponding layer of the sidewall of the conductive support hole are arranged in the same layer successively.

Preferably, wherein, in the conductive beam and the conductive support hole connected with the conductive beam, a first lower release protective layer, a first electrical connection layer, and a first upper release protective layer are sequentially arranged on the sidewall of the conductive support hole along the inner diameter direction of the conductive support hole, one side of the conductive beam, which closes to the infrared detection region, is outwardly successively provided with a second lower release protective layer, a second electrical connection layer, and a second upper release protective layer; the first lower release protective layer of the conductive support hole is connected with the second lower release protective layer of the conductive beam, the first upper release protective layer of the conductive support hole is connected with the second upper release protective layer of the conductive beam, and the first electrical connection layer of the conductive support hole is connected with the second electrical connection layer of the conductive beam;

or, in the conductive beam and the conductive support hole connected with the conductive beam, the sidewall of the conductive support hole is sequentially provided with a first release protective layer and a first electrical connection layer in sequence, or a first electrical connection layer and a first release protective layer in sequence along the inner diameter direction of the conductive support hole; one side of the conductive beam, which closes to the infrared detection region, is outwardly successively provided with a second release protective layer and a second electrical connection layer in sequence, or a second electrical connection layer and a second release protective layer in sequence; the first release protective layer of the conductive support hole is connected with the second release protective layer of the conductive beam, and the first electrical connection layer of the conductive support hole is connected with the second electrical connection layer of the conductive beam;

or, in the conductive beam and the conductive support hole connected with the conductive beam, the sidewall of the conductive support hole is formed by the first electrical connection layer, the conductive beam is formed by the second electrical connection layer; the first electrical connection layer is connected with the second electrical connection layer.

Preferably, wherein the horizontal width of each layer in the conductive beam is smaller than the thickness of a corresponding layer at the top of the support hole.

Preferably, wherein the sidewall of the conductive support hole is in a stair-step shape.

In order to achieve the above object, the present disclosure further provides a manufacturing method of a small-size infrared sensor structure, wherein comprising the following steps:

Step 01: providing a semiconductor device substrate; wherein the surface of the semiconductor device substrate is provided with an interconnection layer:

Step 02: depositing a sacrificial layer on the interconnection layer on the surface of the semiconductor device substrate;

Step 03: defining an infrared detection region, a conductive beam region and a conductive support hole region on the sacrificial layer; etching the sacrificial layer of the conductive support hole region to form support holes, and meanwhile etching the sacrificial layer of the conductive beam region to form trenches; one end of the trench in the length direction intersects with the support hole, and the other end of the trench in the length direction intersects with the infrared detection region;

Step 04: depositing a conductive material and an infrared-sensitive material layer on the semiconductor device substrate after completing the Step 03, the conductive material and the infrared-sensitive material layer cover the sidewall and the bottom of the trench, the sidewall and the bottom of the support hole, and exposed surface of the sacrificial layer:

Step 05: patterning the conductive material and the infrared-sensitive material layer to form a pattern of the infrared detection region and a pattern of the conductive support hole, meanwhile, removing the conductive material and the infrared-sensitive material layer at the bottom of the trench and the outer side of the top of the trench, and the conductive material and the infrared-sensitive material layer of the sidewall of the trench are retained, so that the conductive beam is formed on the sidewall of the trench, and the conductive support hole is formed in the support hole:

Step 06: releasing all of the sacrificial layers by adopting a release process.

Preferably, wherein, in the step 03: the sacrificial layer is etched by adopting a Damascus process so that a contact hole and the trench with stepped sidewalls are obtained.

In order to achieve the object, the present disclosure further provides a manufacturing method of the small-size infrared sensor structure, wherein comprising the following steps:

Step 01: providing a semiconductor device substrate; wherein the surface of the semiconductor device substrate is provided with an interconnection layer;

Step 02: depositing a sacrificial layer on the interconnection layer on the surface of the semiconductor device substrate;

Step 03: defining an infrared detection region, a conductive beam region and a conductive support hole region on the sacrificial layer; etching the sacrificial layer of the conductive support hole region to form support holes, and meanwhile etching the sacrificial layer of the conductive beam region to form trenches; one end of the trench in the length direction intersects with the support hole, and the other end of the trench in the length direction intersects with the infrared detection region:

Step 04: depositing a conductive material and an infrared-sensitive material layer on the semiconductor device substrate after completing the Step 03, wherein, when depositing the infrared-sensitive material layer, all regions other than the infrared detection region are shielded by a mask, and only the infrared detection region is exposed, so that the surface of the sacrificial layer of the infrared detection region is covered with the conductive material and the infrared-sensitive material layer, and the sidewall and the bottom of the trench and the sidewall and the bottom of the support hole are covered with conductive material:

Step 05: patterning the conductive material and the infrared-sensitive material layer, to form a pattern of the infrared detection region and a pattern of the conductive support hole, meanwhile, removing the conductive material at the bottom of the trench and the outer side of the top of the trench, and the conductive material on the sidewall of the trench is retained, so that the conductive beam is formed on the sidewall of the trench, and the conductive support hole is formed in the support hole:

Step 06: releasing all of the sacrificial layers by adopting a release process.

Preferably, wherein, in the step 03: the sacrificial layer is etched by adopting a Damascus process so that a contact hole and the trench with stepped sidewalls are obtained.

The present disclosure discloses a small-size infrared sensor structure and a manufacturing method thereof. A trench is etched in a conductive beam region, and the conductive beam is formed by utilizing the sidewall of the trench so that adjacent pixel structures share a conductive support hole in a small-size infrared sensor, and the integration level of the pixel structures is improved, the area of the infrared detection region in the pixel is enlarged, and the infrared detection efficiency is improved.

### BRIEF DESCRIPTION OF THE DRAWINGS

For a more clear understanding of the objects, features, and advantages of the present disclosure, the preferred embodiments of the present disclosure will be described in detail below with reference to the accompanying drawings, wherein:

FIG. 1 is a top view of a small-sized infrared sensor structure according to a preferred embodiment of the present disclosure

FIG. 2 is a cross-sectional schematic structural diagram along the BB′ direction in FIG. 1

FIG. 3 is a cross-sectional schematic structural diagram of the conductive beam along the AA′ direction in FIG. 1

FIG. 4 is a cross-sectional schematic structural diagram of the contact region of the conductive beam and the infrared detection region along the CC′ direction in FIG. 1

FIG. 5 is a flow diagram of a manufacturing method of a small-size infrared sensor structure according to a preferred embodiment of the present disclosure

FIGS. 6-12 are schematic views of a method for manufacturing a small-sized infrared sensor structure according to a preferred embodiment of the present disclosure

### DETAILED DESCRIPTION

In order to make the contents of the present disclosure more comprehensible, the contents of the present disclosure are further described below in conjunction with the description of the specification. The present disclosure is not limited to the specific embodiment, and general substitutions well known to those skilled in the art are also contemplated within the protection scope of the present disclosure.

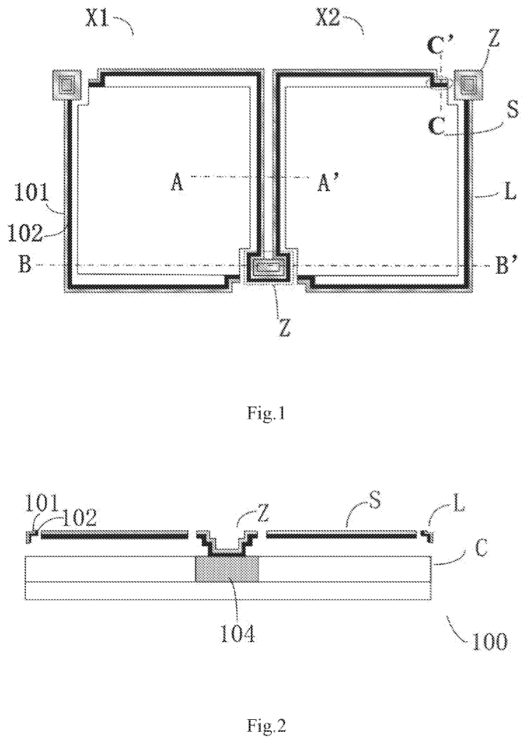

The present disclosure is described in further detail below with reference to FIGS. 1-12 and specific embodiments. It should be noted that the drawings all adopt a very simplified form and use the non-precise proportion and are only used for conveniently and clearly achieving the purpose of assisting in describing the embodiment of the present disclosure.

Referring to FIG. 1, a small-size infrared sensor structure according to an embodiment has a plurality of pixel structures, only two adjacent pixel structures X1 and X2 are illustrated in FIG. 1. Each pixel structure is provided with an infrared detection region S, a conductive beam L which is electrically connected with the infrared detection region S, and a conductive support hole Z used for supporting the conductive beam L and electrically connected with the conductive beam L. The adjacent pixel structures such as X1 and X2 are commonly connected to one conductive support hole Z through one conductive beam L. Here, the conductive beam L is composed of a conductive material 102 and an infrared-sensitive material layer 101, but this is not intended to limit the scope of the present disclosure. As shown in FIG. 1, a semiconductor device substrate 100 is provided with an interconnection layer C, a contact hole 104 is formed in the interconnection layer C, and the interconnection layer C is located on the surface layer of the substrate 100. The conductive material 101 at the bottom of the conductive support hole Z is in contact with the contact hole 104 in the interconnection layer C so that an electrical connection between the conductive support hole Z and the interconnection layer C is realized.

In this embodiment, for ease of expression, in FIG. 1, the conductive support hole Z in the dotted frame represents a schematic structure after the conductive material 102 and the infrared-sensitive material layer 101 are stripped away from the top layer of the conductive support hole Z, the left upper portion and the right upper portion in FIG. 1 are normal top view structural schematic diagrams of the conductive support holes Z. The conductive support holes Z in the dotted frame are shared by adjacent pixel structures. Specifically, the conductive support hole Z in the dotted frame which is commonly connected is arranged below the adjacent infrared detection regions S; taking the centerline of the commonly connected conductive support hole Z in the dotted frame as a symmetry axis, the adjacent pixel structures X1 and X2 are in mirror symmetry. Here, the conductive beam of the pixel structure X1 and the conductive beam of the pixel structure X2 are connected to the conductive support hole Z in the dotted frame.

Here, the conductive beam L and the conductive support hole Z connected with the conductive beam L are formed in the same process, referring to FIG. 1, the sidewalls of the conductive beam L and the sidewall of the conductive support hole Z are arranged in the same layer successively, wherein the hierarchical structure of the conductive beam L and that of the sidewall of the conductive support hole Z are same, and each layer of conductive beam L is arranged in the same layer as the corresponding layer of the sidewall of the conductive support hole Z successively. Certainly, in other embodiments of the present disclosure, the conductive beam L and the conductive support hole Z connected with the conductive beam L can also be separately formed, and the sidewalls of the conductive beam L and the conductive support hole Z are still are arranged in the same layer successively, the hierarchical structure of the conductive beam L and the hierarchical structure of the sidewall of the conductive support hole Z are still same, and each layer of the conductive beam L and the corresponding layer of the sidewall of the conductive support hole Z are still connected to be in the same layer.

Referring to FIG. 1, in the conductive beam L and the conductive support hole Z connected with the conductive beam L, the sidewall of the conductive support hole Z is composed of a first electrical connection layer, the conductive beam L is composed of a second electrical connection layer, and the first electrical connection layer is connected with the second electrical connection layer. Here, a first infrared-sensitive material layer is further formed on the sidewall of the first electrical connection layer, and a second infrared-sensitive material layer is further formed on the sidewall of the second electrical connection layer. In the embodiment, the first electrical connection layer and the second electrical connection layer are the same layers, which is electrical connection layer 102, the first infrared-sensitive material layer and the second infrared-sensitive material layer are the same layer, which is infrared-sensitive material layer 101. In other embodiments of the present disclosure, the first infrared-sensitive material layer and the second infrared-sensitive material layer may not be the same layer, the first electrical connection layer and the second electrical connection layer may not be the same layer.

In other embodiments of the present disclosure, in the conductive beam and the conductive support hole connected with the conductive beam, the sidewall of the conductive support hole is sequentially provided with a first lower release protective layer, a first electrical connection layer and a first upper release protective layer along the inner diameter direction of the conductive support hole; one side of the conductive beam, which closes to the infrared detection region, is outwardly successively provided with a second lower release protective layer, a second electrical connection layer, and a second upper release protective layer, and the first lower release protective layer of the conductive support hole is connected with the second lower release protective layer of the conductive beam, the first upper release protective layer of the conductive support hole is connected with the second upper release protective layer of the conductive beam, the first electrical connection layer of the conductive support hole is connected with the second electrical connection layer of the conductive beam. In another embodiment of the present disclosure, in the conductive beam and the conductive support hole connected with the conductive beam, the sidewall of the conductive support hole is sequentially provided with a first release protective layer and a first electrical connection layer in sequence, or a first electrical connection layer and a first release protective layer in sequence along the inner diameter direction of the conductive support hole, the one side of the conductive beam, which closes to the infrared detection region, is outwardly successively provided with a second release protective layer and a second electrical connection layer in sequence, or a second electrical connection layer and a second release protective layer in sequence; wherein the first release protective layer of the conductive support hole is connected with the second release protective layer of the conductive beam; the first electrical connection layer of the conductive support hole is connected with the second electrical connection layer of the conductive beam.

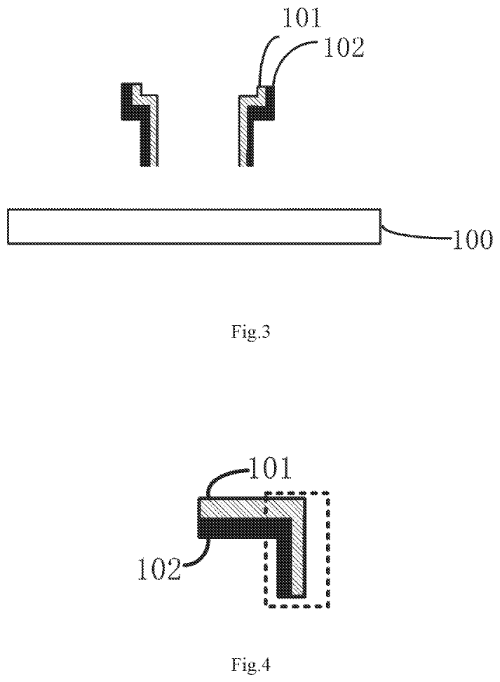

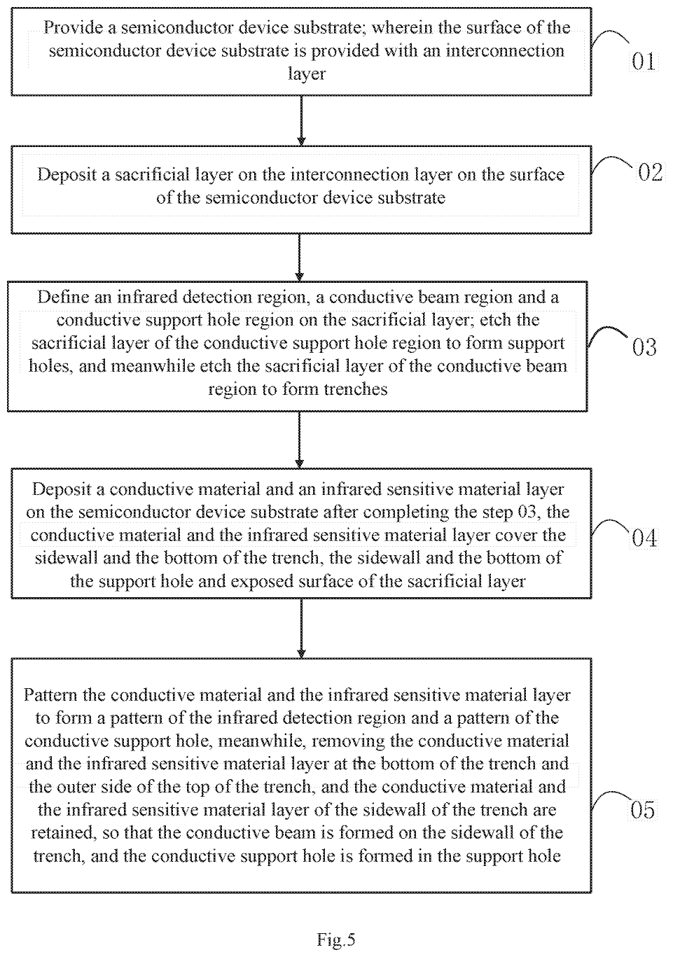

Please refer to FIGS. 2 and 3, FIG. 2 is a cross-sectional schematic structural diagram along the BB′ direction in FIG. 1. FIG. 3 is a cross-sectional schematic structural diagram of the conductive beam along the AA′ direction in FIG. 1. It should be noted that for ease of expression, the interconnection layer and the contact holes in the substrate 100 in FIG. 2 and FIG. 3 are not shown. In the embodiment, the horizontal width of each layer in the conductive beam L is smaller than the thickness of a corresponding layer in the top of the conductive support hole Z, for example, the horizontal width of the infrared-sensitive material layer 101 of the conductive beam L is 60-70% of the horizontal width of the infrared-sensitive material layer 101 at the top of the conductive support hole Z connected with the infrared-sensitive material layer 101. The horizontal width of the electrical connection layer 102 of the conductive beam L is 60-70% of the horizontal width of the electrical connection layer 102 at the top of the conductive support hole Z connected with the electrical connection layer 102. This is because the vertical thickness in the horizontal direction of each layer is greater than the horizontal width of the trench sidewall by controlling the thickness of each deposited layer so that the thickness of each layer in the obtained conductive beam L is smaller than the vertical thickness in the horizontal direction of the corresponding layer. On the premise that the difficulty of lithography and etching are not increasing, the size of the conductive beam is further reduced, the photosensitive area of the infrared detection region is increased, and the conversion efficiency of the infrared detector is improved. Preferably, the horizontal width of the conductive beam is 0.5 nm to 1 nm. Due to the fact that when the horizontal width of the conductive beam is smaller than 0.5 nm, the conductive beams cannot be formed continuously. When the horizontal width of the conductive beam is larger than 1 nm, the size of the conductive beam is too large, so that the loss rate of the infrared light is increased.

In addition, as shown in FIG. 2 and FIG. 3, in order to improve the supporting capability, bending resistance and impact resistance of the conductive support hole Z, the sidewall of the conductive support hole Z is arranged in a stair-step shape. Meanwhile, in order to improve the supporting capability, bending resistance and impact resistance of the conductive beam L, the sidewall of the conductive beam L is also arranged in a stair-step shape.

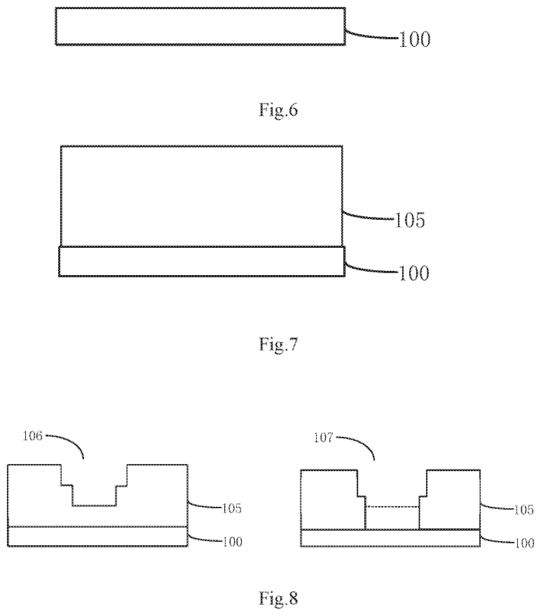

It should be noted that, as shown in FIG. 1, the conductive material 102 and the infrared-sensitive material layer 101 of the conductive beam L are in one-to-one correspondence with the conductive material 102 and the infrared-sensitive material layer 101 of the conductive support hole Z respectively, so that the electrical connection between the conductive beam L and the conductive support hole Z is realized. Please refer to FIG. 4 combining with FIG. 1, FIG. 4 is a cross-sectional schematic structural diagram of the contact region of the conductive beam and the infrared detection region along the CC′ direction in FIG. 1. As shown in FIG. 4, the conductive material 102 and the infrared-sensitive material layer 101, which are at the end of the conductive beam L in contact with the infrared detection region S and are on the sidewall with direction perpendicular to the length direction of the conductive beam L (as shown in the dotted line frame in FIG. 4, and the elliptical dotted line in FIG. 1), are in one-to-one correspondence with the conductive material 102 and the infrared-sensitive material layer 101 of the infrared detection region S successively, so that the electrical connection between the conductive beam L and the infrared detection region S is realized.

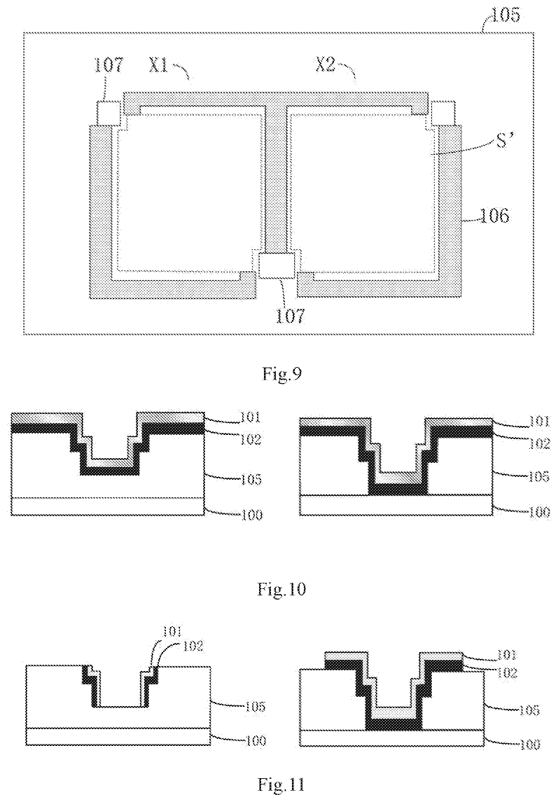

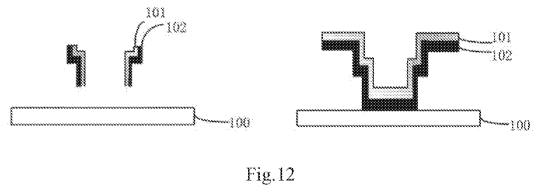

Referring to FIGS. 5-10, in order to facilitate expression, only the schematic structural diagram for manufacturing the conductive beam and the schematic structural diagram for manufacturing the support hole are illustrated in FIGS. 6-10, and other structures are not illustrated. The present disclosure discloses a manufacturing method of a small-size infrared sensor structure, the manufacturing method comprises the following steps:

Step 01: referring to FIG. 6, providing a semiconductor device substrate 100; wherein an interconnection layer (not shown) is arranged on the surface of the semiconductor device substrate 100.

Specifically, the interconnection layer on the surface layer of the semiconductor device substrate 100 can be an interconnection layer prepared by a front end of line interconnection process.

Step 02: referring to FIG. 7, depositing a sacrificial layer 105 on the interconnection layer on the surface of the semiconductor device substrate 100.

Specifically, the sacrificial layer 105 can be deposited on the surface of the interconnection layer on the semiconductor device substrate 100 by a chemical vapor deposition method. The sacrificial layer 105 can be made using a conventional sacrificial layer material, such as inorganic sacrificial layer material silicon oxide or organic sacrificial layer material.

Step 03: referring to FIG. 8 and FIG. 9, defining an infrared detection regions S′ (dotted lines in FIG. 9), a conductive beam region and a conductive support hole region on the sacrificial layer 105; etching the sacrificial layer 105 of the conductive support hole region to form support holes 107; and meanwhile, etching the sacrificial layer 105 of the conductive beam region to form trenches106. A cross-sectional structure diagram of the trench is shown on the left side of FIG. 8, the cross-sectional structure diagram of the support hole is shown on the right side of FIG. 8. FIG. 9 is a top view of the structure of the substrate 100. It should be noted that the structure contour of the trenches 106 and the support holes 107 are illustrated in FIG. 9, and in order to facilitate expression, the stair-step shape of the trenches 106 and the stair-step shape of the support holes 107 are not shown in FIG. 9.

Specifically, referring to FIG. 9, one end of the trench 106 in the length direction intersects with the support hole 107, and the other end of the trench 106 in the length direction intersects with the infrared detection region S′. Before etching, the patterns of the infrared detection region, the conductive beam region, and the conductive support hole region are prepared for forming a pattern in a mask, the pattern of the mask can reference to the top view structure of the substrate shown in FIG. 9. Then, the support hole 107 and the trench 106 are etched at the corresponding positions of the sacrificial layer 105 through the prepared mask. Please refer to FIG. 8, the sacrificial layer 105 can be etched by adopting a Damascus process so that the contact hole 107 and the trench 106 with stair-step shape sidewalls are obtained. It should be noted here that, the depth of the trench 106 determines the height of the conductive beam L, and generally, the depth of the support hole 107 is greater than the depth of the trench 106: wherein the dotted line in the structural diagram of the support hole on the right side in FIG. 8 represents the position where the bottom of the trench is located.

Step 04: please refer to FIG. 10, a cross-sectional structural schematic diagram of the trench with a deposition material is shown on the left side of FIG. 10, and a cross-sectional structural schematic diagram of the support hole with a deposition material on the right side of FIG. 10. Here, a conductive material 102 layer and an infrared-sensitive material layer 101 are deposited on the semiconductor device substrate 100 after the step 03 is completed, and the conductive material 102 and the infrared-sensitive material layer 101 are subjected to doping treatment through ion implantation, with reference to FIG. 9, the conductive material 102 and the infrared-sensitive material layer 101 are covered on the sidewall and the bottom of the trench 106, the sidewall and the bottom of the support hole 107, and exposed surface of the sacrificial layer 105.

It should be noted that the deposition sequence for the conductive material 102 and the infrared-sensitive material layer 101 can be interchanged. If the infrared-sensitive material layer 101 is deposited first, one step that etching away the infrared-sensitive material layer 101 at the bottom of the support hole 107 is needed to add before the conductive material 102 is deposited, so that the subsequently-deposited conductive material 102 in the support hole 107 can be electrically connected with the contact hole of the interconnection layer.

In addition, in the present embodiment, before depositing the conductive material 102 and the infrared-sensitive material layer 101, the method further includes depositing a lower release protective layer on the semiconductor device substrate 100 after completing Step 03; and/or further depositing a layer of upper release protective layer after the conductive material 102 and the infrared-sensitive material layer 101 are deposited. The deposition method for the upper release protective layer and the lower release protective layer can be but not limited to a chemical vapor deposition method, which is known by those skilled in the art and is not further described herein.

Refer to FIG. 11 combining with FIG. 8 and FIG. 1, a cross-sectional schematic structural diagram of a patterned trench is shown on the left side of FIG. 11, a cross-sectional schematic structural diagram of a patterned support hole is shown on the right side in FIG. 11. In Step 05: patterning the conductive material 102 and the infrared-sensitive material layer 101 to form a pattern of the infrared detection region S and a pattern of the conductive support hole Z, meanwhile, removing the conductive material 102 and the infrared-sensitive material layer 101 at the bottom of the trench 106 and the outer side of the top of the trench 106, and the conductive material 102 and the infrared-sensitive material layer 101 of the sidewall of the trench 106 are retained, so that the conductive beam L is formed on the sidewall of the trench, and the conductive support hole Z is formed in the support hole 107.

Specifically, the conductive material 102 and the infrared-sensitive material layer 101 can be patterned without limitation by a lithography and etching process so that the pattern for the infrared detection region S and the pattern for the conductive support hole Z are formed, then the conductive support hole Z is formed in the support hole 107. The conductive material 102 and the infrared-sensitive material layer 101 at the bottom of the trench 106 and the conductive material 102 and the infrared-sensitive material layer 101 on the outer side of the top of the trench 106 are simultaneously removed during etching, the conductive material 102 and the infrared-sensitive material layer 101 on the sidewall of the trench 106 is retained to form the conductive beam L. It should be noted that, referring to FIG. 11 again and with reference to FIG. 1 and FIG. 8, the conductive material 102 and the infrared-sensitive material layer 101 on the sidewall of the trench 106 are in one-to-one correspondence with the conductive material 102 and the infrared-sensitive material layer 101 on the sidewall of the support hole 107, so that the electrical connection between the conductive beam L and the conductive support hole Z is realized. The conductive material 102 and the infrared-sensitive material layer 101, which are at one end of the trench 106 in contact with the infrared detection region S and are on the sidewall with direction perpendicular to the length direction of the trench 106 (shown in the elliptical dotted line in FIG. 1), are in one-to-one correspondence with the corresponding conductive material 102 and the infrared-sensitive material layer 101 of the infrared detection region S respectively, so that the electrical connection between the conductive beam L and the infrared detection region S is realized.

It should be noted that the reason for forming the conductive beam L by using the material deposited on the sidewall of the trench 106 is that, the width of the deposited conductive beam L in the horizontal direction is smaller than the sum of the thickness of the conductive material 102 and the infrared-sensitive material layer 101 deposited on the surface of the sacrificial layer 105 so that the size of the conductive beam L is reduced by ingeniously utilizing the material deposition of the sidewall of the trench 106; meanwhile, a conventional anisotropic etching process can be used for etching away the conductive material 102 and the infrared-sensitive material layer 101 on the outer side of the top of the trench 106 and at the bottom of the trench 106, and the process difficulty is not increased. Therefore, under the condition that a small-size lithographing process is not required, the size of the conductive beam L can be reduced by adopting existing processes. Preferably, the width of the conductive beam L in the horizontal direction is 60-70% of the total thickness of the conductive material 102 and the infrared-sensitive material layer 101 deposited on the surface of the sacrificial layer 105.

Step 06: referring to FIG. 12, a cross-sectional schematic structural diagram of the trench after the sacrificial layer is released is shown on the left side of FIG. 12, a cross-section schematic structural diagram of the support hole after the sacrificial layer is released is shown on the right side in FIG. 12. Here, referring to FIG. 11, a release process is adopted to release all of the sacrificial layers 105.

In particular, the conventional release processes can be adopted, and the method can be known by those skilled in the art and is not further described herein.

It should be noted that in other embodiments of the present disclosure, in the Step 04: depositing a conductive material 102 and the infrared-sensitive material layer 101 on the semiconductor device substrate 100 after completing the Step 03, wherein, when the infrared-sensitive material layer 101 is deposited, all regions other than the infrared detection region S can be completely shielded by a mask, only the infrared detection region S is exposed, so that the surface of the sacrificial layer 105 of the infrared detection region S is covered with the conductive material 102 and the infrared-sensitive material layer 101, and the sidewall and the bottom of the trench 106 and the sidewall and the bottom of the support hole 107 are only covered with the conductive material 102. In this way, the Step 05 can specifically comprise the following Steps: patterning the conductive material 102 and the infrared-sensitive material layer 101 to form the pattern of the infrared detection region S and the pattern of the conductive support hole Z, meanwhile, removing the conductive material 102 at the bottom of the trench 106 and the outer side of the top of the trench 106, and the conductive material 102 on the sidewall of the trench 106 is retained, so that the conductive beam L is formed on the sidewall of the trench 106, and the conductive support hole Z is formed in the support hole 107 so that the subsequently obtained conductive beam L and the conductive support hole 107 do not include the infrared-sensitive material layer 101.

While the present disclosure has been particularly shown and described with references to preferred embodiments thereof it will be understood by those skilled in the art that various changes in form and details may be made therein without departing from the spirit and scope of the present disclosure as defined by the appended claims.

What is claimed is:

1. A small-size infrared sensor structure, comprising:
a plurality of pixels, each pixel has an infrared detection region, a conductive beam electrically connected to the infrared detection region, and a conductive support hole used for supporting the conductive beam and electrically connected with the conductive beam, wherein adjacent pixel structures are commonly connected to one conductive support hole through the conductive beam.

2. The small-size infrared sensor structure of claim 1, wherein the commonly connected conductive support hole is arranged below the adjacent infrared detection regions; taking the centerline of the commonly connected conductive support hole as a symmetry axis, the adjacent pixel structures are in mirror symmetry.

3. The small-size infrared sensor structure of claim 1, wherein the sidewall of the conductive beam and the sidewall of the conductive support hole are arranged in the same layer successively, wherein the hierarchical structure of the conductive beam and that of the sidewall of the conductive support hole are same.

4. The small-size infrared sensor structure of claim 3, wherein, in the conductive beam and the conductive support hole connected with the conductive beam, the sidewall of the conductive support hole is sequentially provided with a first lower release protective layer, a first electrical connection layer and a first upper release protective layer along the inner diameter direction of the conductive support hole; one side of the conductive beam, which closes to the infrared detection region, is outwardly successively provided with a second lower release protective layer, a second electrical connection layer, and a second upper release protective layer; the first lower release protective layer of the conductive support hole is connected with the second lower release protective layer of the conductive beam, and the first upper release protective layer of the conductive support hole is connected with the second upper release protective layer of the conductive beam, and the first electrical connection layer of the conductive support hole is connected with the second electrical connection layer of the conductive beam;
or, in the conductive beam and the conductive support hole connected with the conductive beam, the sidewall of the conductive support hole is sequentially provided with a first release protective layer and a first electrical connection layer in sequence, or a first electrical connection layer and a first release protective layer in sequence along the inner diameter direction of the conductive support hole; one side of the conductive beam, which closes to the infrared detection region, is outwardly successively provided with a second release protective layer and a second electrical connection layer in sequence, or a second electrical connection layer and a second release protective layer in sequence; the first release protective layer of the conductive support hole is connected with the second release protective layer of the conductive beam, and the first electrical connection layer of the conductive support hole is connected with the second electrical connection layer of the conductive beam;
or, in the conductive beam and the conductive support hole connected with the conductive beam, the sidewall of the conductive support hole is formed by the first electrical connection layer, the conductive beam is formed by the second electrical connection layer; the first electrical connection layer is connected with the second electrical connection layer.

5. The small-size infrared sensor structure of claim 3, wherein the horizontal width of each layer in the conductive beam is smaller than the thickness of a corresponding layer at the top of the support hole.

6. The small-size infrared sensor structure of claim 1, wherein the sidewall of the conductive support hole is in a stair-step shape.

7. A manufacturing method of a small-size infrared sensor structure, wherein comprising the following steps:
Step 01: providing a semiconductor device substrate; wherein the surface of the semiconductor device substrate is provided with an interconnection layer;
Step 02: depositing a sacrificial layer on the interconnection layer on the surface of the semiconductor device substrate;
Step 03: defining an infrared detection region, a conductive beam region and a conductive support hole region on the sacrificial layer; etching the sacrificial layer of the conductive support hole region to form support holes, and meanwhile etching the sacrificial layer of the conductive beam region to form trenches; one end of the trench in the length direction intersects with the support hole, and the other end of the trench in the length direction intersects with the infrared detection region;
Step 04: depositing a conductive material and an infrared-sensitive material layer on the semiconductor device substrate after completing the Step 03, the conductive material and the infrared-sensitive material layer cover the sidewall and the bottom of the trench, and exposed surface of the sacrificial layer;
Step 05: patterning the conductive material and the infrared-sensitive material layer to form a pattern of the infrared detection region and a pattern of the conductive support hole, meanwhile, removing the conductive material and the infrared-sensitive material layer at the bottom of the trench and the outer side of the top of the trench, and the conductive material and the infrared-sensitive material layer of the sidewall of the trench are retained, so that the conductive beam is formed on the sidewall of the trench, and the conductive support hole is formed in the support hole;
Step 06: releasing all of the sacrificial layers by adopting a release process.

8. The manufacturing method of a small-size infrared sensor structure of claim 7, wherein, in the step 03: the sacrificial layer is etched by adopting a Damascus process so that a contact hole and the trench with stepped sidewalls are obtained.

9. A manufacturing method of the small-size infrared sensor structure of claim 4, wherein comprising the following steps:
Step 01: providing a semiconductor device substrate; wherein the surface of the semiconductor device substrate is provided with an interconnection layer;
Step 02: depositing a sacrificial layer on the interconnection layer on the surface of the semiconductor device substrate;
Step 03: defining an infrared detection region, a conductive beam region and a conductive support hole region on the sacrificial layer; etching the sacrificial layer of the conductive support hole region to form support holes, and meanwhile etching the sacrificial layer of the conductive beam region to form trenches; one end of the trench in the length direction intersects with the support hole, and the other end of the trench in the length direction intersects with the infrared detection region;
Step 04: depositing a conductive material and an infrared-sensitive material layer on the semiconductor device substrate after completing the Step 03, wherein, when depositing the infrared-sensitive material layer, all regions other than the infrared detection region are shielded by a mask, and only the infrared detection region is exposed, so that the surface of the sacrificial layer of the infrared detection region is covered with the conductive material and the infrared-sensitive material layer, and the sidewall and the bottom of the trench and the sidewall and the bottom of the support hole are covered with conductive material;
Step 05: patterning the conductive material and the infrared-sensitive material layer, to form a pattern of the infrared detection region and a pattern of the conductive support hole, meanwhile, removing the conductive material at the bottom of the trench and the outer side of the top of the trench, and the conductive material on the sidewall of the trench is retained, so that the conductive beam is formed on the sidewall of the trench, and the conductive support hole is formed in the support hole;
Step 06: releasing all of the sacrificial layers by adopting a release process.

10. The manufacturing method of a small-size infrared sensor structure of claim 9, wherein, in the step 03: the sacrificial layer is etched by adopting a Damascus process so that a contact hole and the trench with stepped sidewalls are obtained.
